(19) United States
(12) Patent Application Publication
(10) Pub. No.: US 2019/0287790 A1
(43) Pub. Date: Sep. 19, 2019

(54) LASER IRRADIATION APPARATUS AND METHOD OF MANUFACTURING THIN FILM TRANSISTOR

(71) Applicant: V Technology Co., Ltd., Yokohama (JP)

(72) Inventors: Michinobu Mizumura, Yokohama (JP); Toshinari Arai, Yokohama (JP); Makoto Hatanaka, Yokohama (JP); Takuro Takeshita, Yokohama (JP)

(21) Appl. No.: 16/465,050

(22) PCT Filed: Nov. 22, 2017
(86) PCT No.: PCT/JP2017/042107

§ 371 Date: May 29, 2019

(30) Foreign Application Priority Data
Nov. 30, 2016 (JP) 2016-232505
Dec. 27, 2016 (JP) 2016-253448

(51) Int. Cl. H01L 21/02; H01L 29/66; H01L 21/67

(52) U.S. Cl. CPC H01L 21/0268; H01L 21/67115; H01L 29/6675

(57) ABSTRACT

A laser irradiation apparatus includes a light source configured to generate a laser beam, a projection lens configured to irradiate a predetermined region of an amorphous silicon thin film deposited on each of a plurality of thin film transistors on a glass substrate with the laser beam, and a projection mask pattern provided on the projection lens and including a plurality of masks to which transmittances that are proportions of laser beams passing therethrough are set, wherein the projection lens irradiates the plurality of thin film transistors on the glass substrate moving in a predetermined direction with the laser beam via the plurality of masks included in the projection mask pattern, and each of the plurality of masks included in the projection mask pattern is set to any one of the plurality of transmittances.

### TECHNICAL FIELD

This disclosure relates to formation of a thin film transistor, more particularly, to a laser irradiation apparatus and a method of manufacturing a thin film transistor capable of forming a polysilicon thin film by irradiating an amorphous silicon thin film on the thin film transistor with a laser beam.

### BACKGROUND

A transistor in which an amorphous silicon thin film is used in a channel region may be provided as a thin film transistor with an inverse staggered structure. However, since an amorphous silicon thin film has low electron mobility, when an amorphous silicon thin film is used in the channel region, there is a drawback that the mobility of electric charges in the thin film transistor becomes low.

Thus, a method of polycrystallizing a predetermined region of the amorphous silicon thin film by instantly heating the predetermined region using a laser beam, forming a polysilicon thin film having a high electron mobility, and using the polysilicon thin film in the channel region may be provided.

For example, Japanese Unexamined Patent Application Publication No. 2016-100537 discloses that processing of crystallizing a polysilicon thin film is performed through melting and solidifying over a short time by forming an amorphous silicon thin film in a channel region and then performing laser annealing by irradiating the amorphous silicon thin film with a laser beam such as an excimer laser or the like. In addition, Japanese Unexamined Patent Application Publication No. 2016-100537 discloses a principle in which a channel region between a source and a drain of a thin film transistor can be constituted of a polysilicon thin film having a high electron mobility, and a high speed in a transistor operation becomes possible due to this processing being performed.

In the thin film transistor disclosed in Japanese Unexamined Patent Application Publication No. 2016-100537, the channel region between the source and the drain is constituted of a polysilicon thin film in one place (at one piece). For this reason, the properties of the thin film transistor depend on the polysilicon thin film of the one place (the one piece).

Since the energy density of the laser beam from an excimer laser or the like varies between instances of irradiation (shots) thereof, the electron mobility of a polysilicon thin film formed using the laser beam also varies. For this reason, the properties of the thin film transistor formed using the polysilicon thin film also depend on the variation in energy density of the laser beam.

As a result, variation may occur in the properties of a plurality of thin film transistors included in a glass substrate.

Thus, it could be helpful to provide a laser irradiation apparatus and a method of manufacturing a thin film transistor in which variation in properties of a plurality of thin film transistors included in a glass substrate is minimized.

### SUMMARY

We thus provide:

A laser irradiation apparatus includes a light source configured to generate a laser beam; a projection lens configured to irradiate a predetermined region of an amorphous silicon thin film deposited on each of a plurality of thin film transistors on a glass substrate with the laser beam; and a projection mask pattern provided on the projection lens and including a plurality of masks for which transmittances that are proportions of the laser beam passing therethrough are set, wherein the projection lens irradiates the plurality of thin film transistors on the glass substrate moving in a predetermined direction with the laser beam via the plurality of masks included in the projection mask pattern, and each of the plurality of masks included in the projection mask pattern is set to any one of a plurality of transmittances.

Masks to which different transmittances are set may be randomly disposed in the projection mask pattern.

Each of the plurality of masks included in the projection mask pattern may be set to any one of the transmittances included in a predetermined range that is previously determined.

The laser irradiation apparatus may be constituted of a plurality of microlenses included in a microlens array that are able to divide the laser beam, and the plurality of masks included in the projection mask pattern may correspond to the plurality of microlenses, respectively.

Masks included in the projection mask pattern and neighboring in a column perpendicular to the predetermined direction may have different transmittances.

The plurality of masks included in the projection mask pattern may have different transmittances.

Transmittance of a mask corresponding to each of the microlenses in the projection mask pattern may be set on the basis of the properties of the plurality of microlenses included in the microlens array.

The projection mask pattern may be a phase-shifting mask configured to increase a resolution of the microlens by altering a phase of a laser beam passing through the microlens, and the phase-shifting mask may alter a phase of a laser beam passing through a microlens determined on the basis of a resolution among the plurality of microlenses and increase the resolution of this microlens.

The phase-shifting mask may alter a phase of the laser beam passing through the microlens having a relatively low resolution among the plurality of microlenses and increase the resolution of the microlens.

The projection lens may irradiate a predetermined region of an amorphous silicon thin film deposited between a source electrode and a drain electrode included in a thin film transistor with a laser beam and form a polysilicon thin film.

A method of manufacturing a thin film transistor includes a first step of generating a laser beam; a second step of irradiating a predetermined region of an amorphous silicon thin film deposited on a plurality of thin film transistors on a glass substrate with the laser beam using a projection lens on which a projection mask pattern including a plurality of masks, to which transmittances that are proportions of laser beams passing therethrough are set, is provided; and a third step of moving the glass substrate in a predetermined direction whenever the laser beam is radiated, wherein, in the second step, the laser beam is radiated via the projection mask pattern including the plurality of masks to which any one of the plurality of transmittance is set.

In the second step, the laser beam may be radiated via the projection mask pattern on which the masks, to which different transmittances are set, are randomly disposed.

In the second step, the laser beam may be radiated via the projection mask pattern including the mask to which any one of the transmittances included in a predetermined range that is previously determined is set.

It is thus possible to provide a laser irradiation apparatus and a method of manufacturing a thin film transistor that are capable of suppressing variation in properties of a plurality of thin film transistors included in a glass substrate.

### BRIEF DESCRIPTION OF THE DRAWINGS

FIG. 1 is a view showing a configuration example of a laser irradiation apparatus 10.

FIG. 2 is a view showing a configuration example of a microlens array 13.

FIG. 3 is a schematic view showing an example of a thin film transistor 20 in which a predetermined region is annealed.

FIG. 4 is a schematic view showing an example of a glass substrate 30 irradiated with a laser beam 14 by the laser irradiation apparatus 10.

FIGS. 5(a) and 5(b) are schematic views showing another example of the glass substrate 30 irradiated with a laser beam 14 by the laser irradiation apparatus 10.

FIG. 6 is a schematic view showing a configuration example of a projection mask pattern 15 provided on the microlens array 13.

FIG. 7 is a schematic view showing another configuration example of the projection mask pattern 15 provided on the microlens array 13.

FIG. 8 is a view showing another configuration example of the laser irradiation apparatus 10.

FIG. 9 is a view showing another configuration example of the microlens array 13.

FIG. 10 is a view showing another configuration example of the laser irradiation apparatus 10.

### REFERENCE SIGNS LIST

10 laser irradiation apparatus
11 laser source
12 coupling optical system
13 microlens array
14 laser beam
15 projection mask pattern
16 transmissive region
17 microlens
18 projection lens
19 phase-shifting mask
20 thin film transistor
21 amorphous silicon thin film
22 polysilicon thin film
23 source
24 drain
30 glass substrate

### DETAILED DESCRIPTION

Hereinafter, examples will be described in detail with reference to the accompanying drawings.

### First Example

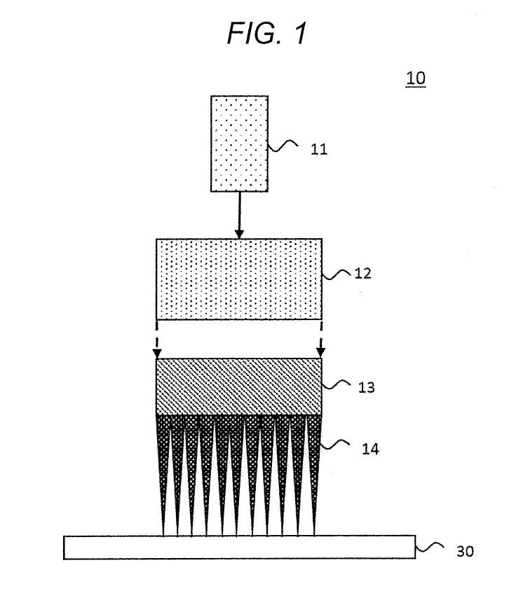

FIG. 1 is a view showing a configuration example of a laser irradiation apparatus 10 according to a first example.

In the first example, the laser irradiation apparatus 10 is, for example, an apparatus that irradiates only a region in which a channel region is intended to be formed with a laser beam to anneal the region in which a channel region is intended to be formed and polycrystallizing the region in which a channel region is intended to be formed in a process of manufacturing a semiconductor device such as a thin film transistor (TFT) 20.

The laser irradiation apparatus 10 is used, for example, when a thin film transistor is formed for the pixels of a peripheral circuit or the like of a liquid crystal display device. When such a thin film transistor is formed, first, a gate electrode formed of a metal film of, for example, Al or the like, is formed as a pattern on a glass substrate 30 through sputtering. Then, a gate insulating film constituted of a SiN film is formed on the entire surface of the glass substrate 30 through a low-temperature plasma CVD method. After that, for example, an amorphous silicon thin film 21 is formed on the gate insulating film through, for example, a plasma CVD method. Then, a predetermined region on a gate electrode of the amorphous silicon thin film 21 is irradiated with a laser beam 14 and annealed using the laser irradiation apparatus 10 as exemplified in FIG. 1, and the predetermined region is polycrystallized to become polysilicon.

As shown in FIG. 1, in the laser irradiation apparatus 10, a beam system of a laser beam emitted from a laser source 11 is expanded by a coupling optical system 12, and a luminance distribution is uniformized. The laser source 11 is, for example, an excimer laser configured to radiate a laser beam having a wavelength of 308 nm, 248 nm, or the like, with a predetermined repeating cycle time.

After that, the laser beam is divided into a plurality of laser beams 14 by a plurality of openings (transmissive regions), not shown, of a projection mask pattern 15 provided on a microlens array 13, and radiated to a predetermined region of the amorphous silicon thin film 21. The projection mask pattern 15 is provided on the microlens array 13, and the laser beams 14 are radiated to a predetermined region using the projection mask pattern 15. Then, the predetermined region of the amorphous silicon thin film 21 is instantly heated and melted, and a part of the amorphous silicon thin film 21 becomes a polysilicon thin film 22.

The polysilicon thin film 22 has a higher electron mobility than that of the amorphous silicon thin film 21, and is used in a channel region in the thin film transistor 20 that electrically connects a source 23 and a drain 24. Further, while an example using the microlens array 13 has been exemplified in the example of FIG. 1, there is no necessity to use the microlens array 13, and the laser beam 14 may be radiated using one projection lens. Further, in Configuration 1, an example in which the polysilicon thin film 22 is formed using the microlens array 13 will be described.

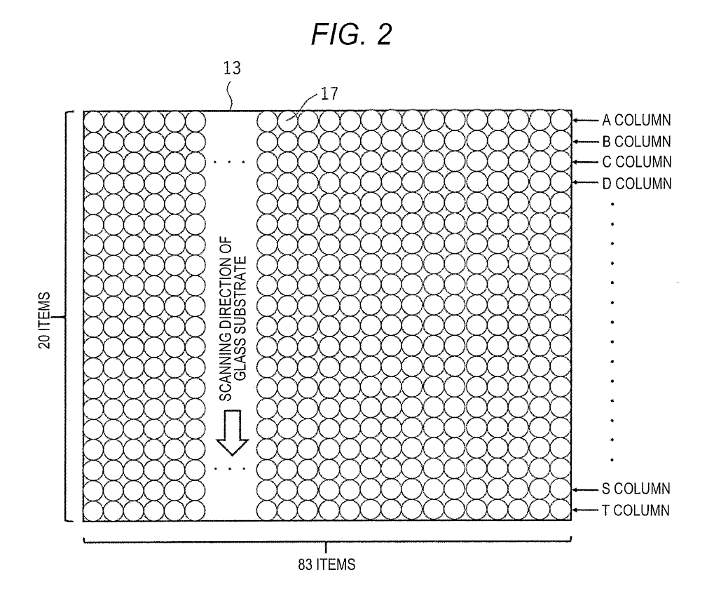

FIG. 2 is a view showing a configuration example of the microlens array 13 used for annealing. As shown in FIG. 2, in the microlens array 13, 20 microlenses 17 are disposed in a column (or a row) in a scanning direction. The laser irradiation apparatus 10 radiates laser beams 14 to one thin film transistor 20 using at least some of the 20 microlenses 17 included in one column (or one row) of the microlens array 13. Further, the number of the microlenses 17 of the one column (or one row) included in the microlens array 13 is not limited to 20 and may be any number.

As shown in FIG. 2, when the microlens array 13 includes 20 microlenses 17 in the one column (or one row), the microlens array 13 includes, for example, 83 microlenses in one row (or one column). Further, although 83 has been taken as an example of a number thereof, naturally it may be any number.

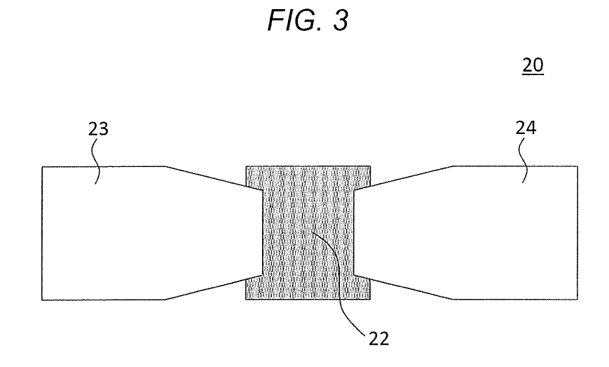

FIG. 3 is a schematic view showing an example of the thin film transistor 20 in which a predetermined region is annealed. Further, the thin film transistor 20 is fabricated by forming the polysilicon thin film 22 first, and then, forming the source 23 and the drain 24 on both ends of the formed polysilicon thin film 22.

As shown in FIG. 3, the thin film transistor has the polysilicon thin film 22 formed between the source 23 and the drain 24. The laser irradiation apparatus 10 irradiates the thin film transistor 20 with laser beams 14 using, for example, the 20 microlenses 17 included in one column (or one row) of the microlens array 13 shown in FIG. 2. That is, the laser irradiation apparatus 10 irradiates the polysilicon thin film 22 with the laser beams 14 of 20 shots. As a result, in the thin film transistor 20, a predetermined region of the amorphous silicon thin film 21 is instantly heated and melted, and becomes the polysilicon thin film 22.

In the polysilicon thin film 22, since an energy density of the laser beam 14 varies at every shot, variation in electron mobility thereof may occur. As described above, this is because the electron mobility of the polysilicon thin film 22 depends on the energy density of the last laser beam 14 radiated to the polysilicon thin film 22, i.e., the energy density of the final shot.

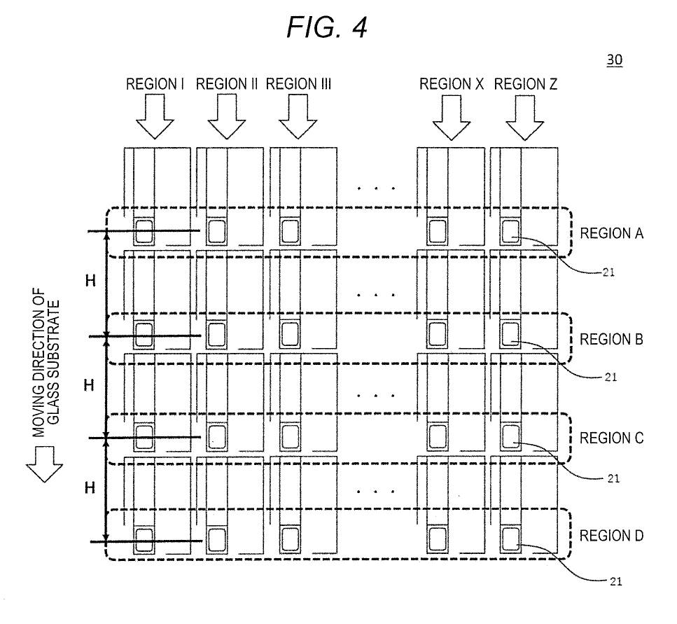

The laser irradiation apparatus 10 irradiates the amorphous silicon thin film 21 with laser beams 14. Here, the laser irradiation apparatus 10 radiates the laser beams 14 at a predetermined period and moves the glass substrate 30 while the laser beams 14 are not radiated, and the laser beams 14 are radiated to a place of the next amorphous silicon thin film 21. As shown in FIG. 4, the glass substrate 30 has the amorphous silicon thin film 21 disposed in a moving direction at predetermined intervals “H.” Then, the laser irradiation apparatus 10 radiates a portion of the amorphous silicon thin film 21 disposed on the glass substrate 30 with laser beams 14 at a predetermined period.

Then, the laser irradiation apparatus 10 irradiates the plurality of amorphous silicon thin films 21 on the glass substrate with the same laser beam 14 using the microlens array 13. The laser irradiation apparatus 10 irradiates the plurality of amorphous silicon thin films 21 included in a region A shown in FIG. 4 with the same laser beam 14. In addition, the laser irradiation apparatus 10 irradiates the plurality of amorphous silicon thin films 21 included in a region B shown in FIG. 4 with the same laser beam 14.

Here, the laser irradiation apparatus 10 is assumed to radiate laser beams 14 using the 20 microlenses 17 included in one column (or one row) of the microlens array 13 shown in FIG. 2 to perform annealing.

In this example, the plurality of amorphous silicon thin films 21 in the region A in FIG. 4 are irradiated first with the laser beams 14 using a first microlens 17a included in the microlens array 13 shown in FIG. 2. After that, the glass substrate 30 is moved by a predetermined interval “H.” The laser irradiation apparatus 10 stops irradiation of laser beams 14 while the glass substrate 30 is moved. Then, after the glass substrate 30 is moved by “H,” the plurality of amorphous silicon thin films 21 in the region A are irradiated with laser beams 14 using a second microlens 17b included in the microlens array 13 shown in FIG. 2. Further, the laser irradiation apparatus 10 may irradiate the glass substrate 30 temporarily stopped after the glass substrate 30 is moved by “H” with laser beams 14, or may irradiate the glass substrate 30 moving continuously with laser beams 14.

Further, an irradiation head (i.e., the laser source 11, the coupling optical system 12, the microlens array 13 and a projection mask 150) of the laser irradiation apparatus 10 may move with respect to the glass substrate 30.

The laser irradiation apparatus 10 repeatedly performs this, and finally, irradiates the plurality of amorphous silicon thin films 21 in the region A with laser beams 14 using a microlens 17t of the microlens array 13 shown in FIG. 2 (i.e., the final microlens 17). As a result, the plurality of amorphous silicon thin films 21 in the region A are radiated with laser beams 14 using the 20 microlenses 17 included in one column (or one row) of the microlens array 13 shown in FIG. 2.

Similarly, the laser irradiation apparatus 10 also irradiates the plurality of amorphous silicon thin films 21 in the region B in FIG. 4 with laser beams 14 using the 20 microlenses 17 included in one column (or one row) of the microlens array 13 shown in FIG. 2. However, since the region B has a position different from the region A by “H” in the moving direction of the glass substrate, a time at which the laser beams 14 are radiated is delayed to the extent of one instance of irradiation. That is, when the plurality of amorphous silicon thin films 21 in the region A are irradiated with laser beams 14 using the second microlens 17b, the plurality of amorphous silicon thin films 21 in the region B are irradiated with laser beams 14 using the first microlens 17a. Then, when the plurality of amorphous silicon thin films 21 in the region A are irradiated with laser beams 14 using a twentieth microlens 17t (i.e., the final microlens 17), the plurality of amorphous silicon thin films 21 in the region B are irradiated with a laser beam using a nineteenth microlens 17s that is one before the final microlens. Then, the plurality of amorphous silicon thin films 21 in the region B are irradiated with laser beams using the twentieth microlens 17t (i.e., the final microlens 17) at timing of irradiation of the next laser beam.

That is, the plurality of amorphous silicon thin films 21 included in the region A and the plurality of amorphous silicon thin films 21 included in the region B shown in FIG. 4 are finally irradiated with different laser beams 14.

In the excimer laser, a stability between pulses is about 0.5%. That is, the laser irradiation apparatus 10 generates variation of about 0.5% in energy density of the laser beam 14 at every shot. For this reason, variation may also occur in electron mobility of the polysilicon thin film 22 formed by the laser irradiation apparatus 10. Then, the electron mobility of the polysilicon thin film 22 formed by radiating the laser beam 14 depends on the energy density of the laser beam 14 finally radiated to the polysilicon thin film 22, i.e., the energy density of the final shot.

For this reason, since the plurality of amorphous silicon thin films 21 included in the region A and the plurality of amorphous silicon thin films 21 included in the region B are irradiated with different laser beams that are finally radiated, electron mobilities of the formed polysilicon thin film 22 differ from each other.

Meanwhile, since the plurality of amorphous silicon thin films 21 included in the region A are irradiated with the finally radiated laser beams 14 that are the same, electron mobility of the formed polysilicon thin film 22 in the region A is the same. This is because the plurality of amorphous silicon thin films 21 included in the region B are also the same and electron mobility of the polysilicon thin film 22 formed in the region B is the same. That is, while electron mobilities between neighboring regions are different on the glass substrate, the plurality of amorphous silicon thin films 21 in the same region have the same electron mobility.

As a result, this causes generation of display unevenness in a liquid crystal screen. As shown in FIG. 4, since a boundary between the region A and the region B has “a linear shape,” the thin film transistors 20 having different properties abut each other at the “linear” boundary, and a difference in display (for example, a difference in gradation or the like of color) due to a difference in properties thereof appears as “a line.” As a result, display unevenness in the liquid crystal screen becomes “a stripe” and is emphasized to an extent that cannot be neglected.

Here, for example, a transmittance of the laser beams 14 radiated to the amorphous silicon thin films 21 included in the substrate 30 is changed using the projection mask pattern 15. For example, variation in transmittance of the laser beams 14 radiated to the amorphous silicon thin films 21 may be maintained. Further, the transmittance is proportion of the laser beams passing through the mask 150.

As described above, when the transmittance of the laser beams 14 varies, the laser beams 14 having different transmittances are radiated to the amorphous silicon thin films 21, and a situation in which all of the amorphous silicon thin films 21 are irradiated with the same laser beam 14 is eliminated. For this reason, even in the plurality of amorphous silicon thin films 21 included in the same region (for example, in the region A), the neighboring amorphous silicon thin films 21 are irradiated with the laser beams 14 having different transmittances. As a result, in the same region (for example, in the region A), transmittances of the laser beams 14 finally radiated to the neighboring amorphous silicon thin films 21 are different from each other. Further, the neighboring amorphous silicon thin films 21 are not necessarily irradiated with the laser beams 14 having different transmittances, the masks having the same transmittance are adjacent to each other depending on disposition of the masks 150 in the projection mask pattern 15, and in this example, the neighboring amorphous silicon thin films 21 are irradiated with the laser beams 14 having the same transmittance. However, in consideration of all of the amorphous silicon thin films 21 included in the substrate 30, since the masks 150 having different transmittances are randomly disposed in the projection mask pattern 15, a probability that the neighboring amorphous silicon thin films 21 are irradiated with the laser beams 14 having different transmittances is increased.

Accordingly, electron mobilities of the neighboring polysilicon thin films 22 in the same region (for example, in the region A) are different from each other. As a result, properties of the neighboring thin film transistors 20 in the same region (for example, in the region A) are also different from each other. Accordingly, in all of the glass substrates 30, properties of the neighboring thin film transistors 20 are different from each other, and a difference in display due to a difference in the properties (for example, a difference in gradation or the like of a color) will not appear in “a linear shape.” For this reason, display unevenness in the liquid crystal screen does not become “a stripe” and the display unevenness can be prevented from being emphasized.

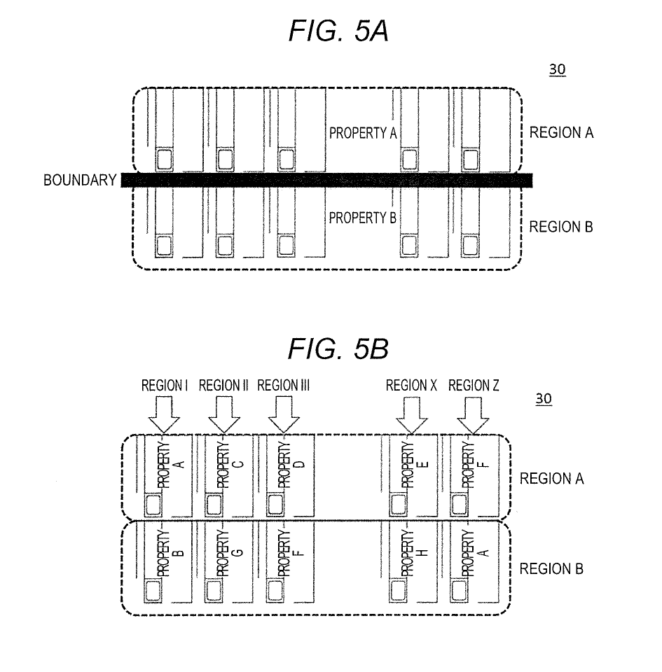

FIGS. 5(a) and 5(b) are views explaining the presence or absence of display unevenness due to the neighboring thin film transistors 20 in the glass substrate 30. In FIG. 5(a), properties of the plurality of thin film transistors 20 in the region A are the same as the properties A, and properties of the plurality of thin film transistors 20 in the region B are the same as the properties B. As a result, in the “linear” boundary between the region A and the region B, the thin film transistor 20 of the properties A butts against the thin film transistor 20 of the properties B, and thus, a difference in display due to a difference in properties is appeared in “a linear shape.” For this reason, display unevenness in the liquid crystal screen becomes “a stripe” and is emphasized.

Meanwhile, in FIG. 5(b), when the neighboring thin film transistors 20 in the same region (the region A/the region B) are irradiated with the laser beams 14 having different transmittances, since the thin film transistors have different properties, a difference in display due to a difference in properties is dispersed, and the difference is not appeared in “a linear shape.” For this reason, display unevenness in the liquid crystal screen can be reduced.

To realize the above-mentioned contents, in the first example, the projection mask pattern 15 provided on the microlens array 13 includes the plurality of masks 150 to which a transmittance that is a laser beam transmission proportion is set. Then, each of the plurality of masks 150 included in the projection mask pattern 15 is set to any one of a plurality of transmittances. The plurality of transmittances is any one of ten kinds of transmittances, for example, 90%, 91%, 92% . . . 100%. Further, the plurality of transmittances are merely exemplary and may be any kind of transmittance. In addition, the plurality of transmittances are not limited to ten and may be any number of transmittances. In addition, the plurality of transmittances may be within any range such as a range of 70% to 100% or the like. The range of the plurality of transmittances may be a predetermined range that is previously determined. For example, the predetermined range may be previously determined to 90% to 100%.

In addition, in the projection mask pattern 15, the masks 150 to which different transmittances are set are randomly disposed.

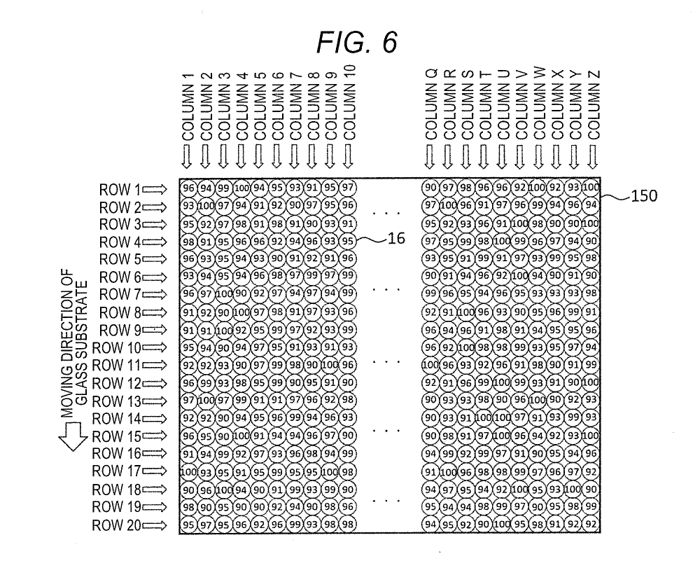

FIG. 6 is a view showing a configuration of the masks 150 of the projection mask pattern 15 in the first example.

As shown in FIG. 6, in the projection mask pattern 15, the masks 150 to which different transmittances are set are randomly disposed. However, the projection mask patterns 15 having different transmittances are not necessarily disposed randomly, and may be disposed on the basis of a predetermined condition. Here, in FIG. 6, numerals written on the projection mask pattern are transmittances of the laser beams 14 in the projection mask pattern. As shown in FIG. 6, in each of the projection mask patterns, for example, the transmittance is set to any one of 90% to 100%. Further, as described above, the transmittance of the projection mask pattern is not necessarily within the range of 90 to 100% and may be any transmittance.

Neighboring projection mask patterns 15 may be disposed such that they have different transmittances. Further, the neighboring projection mask patterns 15 are not necessarily disposed to have different transmittances.

In addition, in each of the plurality of masks included in the projection mask pattern 15, in one column perpendicular to a moving direction (a predetermined direction) of the microlens array 13, the masks 150 may be disposed such that the transmittances of the neighboring masks 150 are different from each other. In this example, in the laser irradiation apparatus 10, in the 20 microlenses 17 included in one column (or one row) of the microlens array 13 shown in FIG. 2 with respect to the one amorphous silicon thin film 21, transmittances of the laser beams 14 radiated from at least the neighboring microlenses 17 are different from each other. For example, in the laser irradiation apparatus 10, when the projection mask patterns having different transmittances are disposed on the 20 microlenses 17 included in one column (or one row) of the microlens array 13, the different amorphous silicon thin films 21 can be irradiated with the laser beams 14 having different transmittances.

In addition, a width of a transmissive region 16 in each of the projection masks pattern 15 is, for example, 4 μm. In addition, an opening section provided in the projection mask pattern 15 shown in FIG. 6 has, for example, a rectangular shape, a long side of which is 20 μm and a short side of which is 10 μm. Further, a size of the opening section of the projection mask pattern 15 is exemplary and may be any size as long as the size corresponds to a size of the microlens 17.

In the example in FIG. 6, the transmissive region 16 of the projection mask pattern 15 is provided to be perpendicular to the moving direction (the scanning direction) of the glass substrate 30. Further, the transmissive region 16 of the projection mask pattern 15 is not necessarily perpendicular to the moving direction (the scanning direction) of the glass substrate 30 and may be provided to be parallel to (substantially parallel to) the moving direction (the scanning direction).

In the laser irradiation apparatus 10, as a result of irradiating the glass substrate 30 exemplified in FIG. 2 with the laser beams 14 using the projection mask pattern 15 shown in FIG. 6, in the same region (for example, in the region A) shown in FIG. 3, for example, the neighboring amorphous silicon thin films 21 are irradiated with the laser beams 14 having different transmittances. For this reason, in the plurality of amorphous silicon thin films 21 included in the same region (for example, in the region A), for example, the laser beams 14 finally radiated to the neighboring amorphous silicon thin films 21 also have different transmittances. As a result, in the same region (for example, in the region A), electron mobilities of the neighboring polysilicon thin films 22 are different from each other.

Then, as described above, since the radiated laser beams 14 are different between the regions perpendicular to the scanning direction (the region A or the region B exemplified in FIG. 3), the thin film transistors 20 of the neighboring regions have different properties.

As a result, in the entire glass substrate 30, the neighboring thin film transistors 20 have different properties. For this reason, a difference in display (for example, a difference in gradation or the like of a color) due to a difference in properties of the thin film transistor 20 is dispersed and does not appear in a linear shape. For this reason, display unevenness in the liquid crystal screen does not become “a stripe” and the display unevenness can be prevented from being emphasized.

In the first example, the glass substrate 30 is moved by a predetermined distance each time the laser beam 14 is radiated by one microlens 17. As shown in FIG. 2, the predetermined distance is a distance “H” between the plurality of thin film transistors 20 on the glass substrate 30. The laser irradiation apparatus 10 stops radiation of the laser beams 14 while the glass substrate 30 is moved by the predetermined distance.

After the glass substrate 30 is moved by the predetermined distance “H,” the laser irradiation apparatus 10 radiates laser beams 14 using the microlenses 17 included in the microlens array 13. Further, in the first example, since the projection mask pattern 15 shown in FIG. 6 is used, the one amorphous silicon thin film 21 is irradiated with laser beams 14 using the five microlenses 17.

Then, after the polysilicon thin film 22 is formed on the thin film transistor 20 of the glass substrate 30 through laser annealing, the source 23 and the drain 24 are formed on the thin film transistor 20 through a separate process.

In this way, in the first example, transmittances of the plurality of masks 150 included in the projection mask pattern 15 are changed such that the masks 150 having different transmittances are randomly disposed in the projection mask pattern 15. As a result, for example, the neighboring amorphous silicon thin films 21 are irradiated with laser beams 14 having different transmittances. For this reason, electron mobilities of the neighboring polysilicon thin films 22 are different from each other. That is, in the entire glass substrate 30, properties of the neighboring thin film transistors 20 are different from each other, and a difference in display (for example, a difference in gradation or the like of a color) due to a difference in the properties does not appear in “a linear shape.” For this reason, display unevenness in the liquid crystal screen does not become “a stripe,” and the display unevenness can be prevented from being emphasized.

### Second Example

A second example is an example in which a transmittance of each of the projection mask patterns 15 varies (adjusted) on the basis of properties of each of the plurality of microlenses 17 included in the microlens array 13.

The plurality of microlenses 17 included in the microlens array 13 have different properties. For example, in the microlenses 17 disposed in the vicinity of a center of the microlens array 13 and the microlenses 17 disposed in a peripheral section, a deviation may occur in the properties thereof. For this reason, the laser beams 14 radiated from the plurality of microlenses 17 have different properties (for example, energy densities) because properties of the microlenses 17 are different from each other. For this reason, even when the laser irradiation apparatus 10 simultaneously radiates laser beams 14 using the plurality of microlenses 17 included in the microlens array 13, since properties of the plurality of microlenses 17 are different from each other, properties (energy densities or the like) of the laser beams 14 are different from each other.

Here, in the second example, transmittance of each of the projection mask patterns 15 is set (adjusted) on the basis of properties of the plurality of microlenses 17 included in the microlens array 13. As a result, a difference in properties of the laser beams 14 radiated using the plurality of microlenses 17 can be reduced.

Each of the plurality of microlenses 17 included in the microlens array 13 shown in FIG. 2 has properties that differ within a range of, for example, 5%. Further, 5% is merely exemplary and properties of the plurality of microlens arrays 13 are different from each other within a range of 5% or more or 5% or less. For example, a difference in properties of the microlenses 17 can be previously ascertained by radiating the laser beams 14 to the microlenses 17 and measuring the properties (for example, an energy density) thereof.

Here, in the second example, transmittance of each of the projection mask patterns 15 is set (adjusted) on the basis of properties of each of the microlenses 17, which is previously ascertained. As a result, when the laser beams 14 are radiated using the microlens array 13 in which the projection mask patterns 15 having the set (adjusted) transmittance are disposed, a difference in properties of the laser beams 14 can be reduced.

For example, when an energy density of the laser beam 14 passing through the one microlens 17 is high, a transmittance of the projection mask pattern 15 disposed on the one microlens 17 is set to a low level. Meanwhile, when an energy density of laser beams 14 passing through another microlens 17 is low, a transmittance of the projection mask pattern 15 disposed on the other microlens 17 is set to a high level. In this way, a difference in properties of the laser beams 14 due to a difference in properties of the microlenses 17 can be reduced by setting (adjusting) a transmittance of the projection mask pattern 15 disposed on the microlenses 17 according to the properties of the microlenses 17.

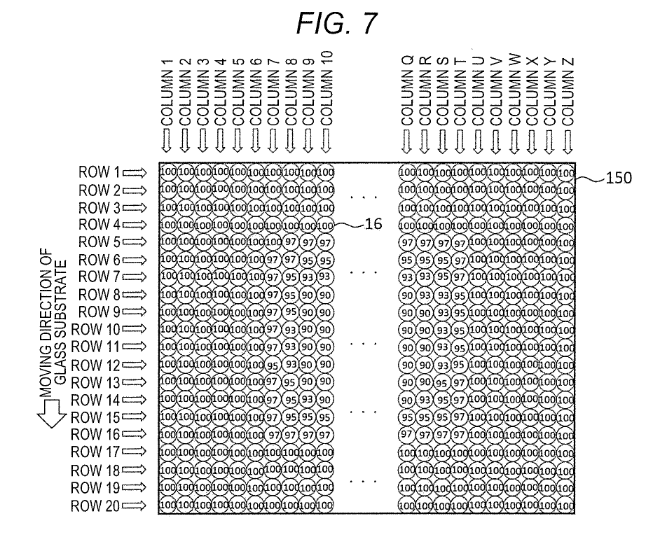

FIG. 7 shows the projection mask pattern 15 including the masks 150, a transmittance of which is set (adjusted) on the basis of properties of the microlenses 17. An example of FIG. 7 is an example of the projection mask pattern 15 when a deviation occurs in properties of the microlenses 17 disposed in the vicinity of a center of the microlens array 13 and the microlenses 17 disposed on a peripheral section thereof.

As shown in FIG. 7, a transmittance of the masks 150 included in the projection mask pattern 15 is set (adjusted) on the basis of properties of the microlens. As a result, the laser irradiation apparatus 10 can reduce a difference in properties of the laser beams 14 due to properties in the microlenses 17 included in the microlens array 13 and radiate the laser beams 14 having substantially the same property by radiating the laser beams 14 using the projection mask pattern shown in FIG. 7.

As described above, in the second example, a difference in properties of the laser beams 14 due to a difference in properties of the microlenses 17 can be reduced by altering (adjusting) a transmittance of each of the plurality of masks 150 included in the projection mask pattern 15 on the basis of properties of the plurality of microlenses 17 contained in the microlens array 13.

### Third Example

A third example is an example when a transmittance of the mask 150 is further changed to vary transmittances of laser beams 14 after altering (adjusting) transmittances of the plurality of masks 150 included in the projection mask pattern 15 on the basis of properties of the plurality of microlenses 17 included in the microlens array 13.

In the third example, first, transmittances of the plurality of masks 150 included in the projection mask pattern 15 are altered (adjusted) on the basis of properties of the plurality of microlenses 17 included in the microlens array 13. As a result, a difference in properties of the laser beams 14 due to properties of the plurality of microlenses 17 included in the microlens array 13 is reduced.

In addition, in the third example, transmittances of the plurality of masks 150 included in the projection mask pattern 15 are changed such that the masks 150 having different transmittances are randomly disposed in the projection mask pattern 15. As a result, for example, the neighboring amorphous silicon thin films 21 radiate the laser beams 14 having different transmittances. For this reason, electron mobilities of the neighboring polysilicon thin films 22 are different from each other. As a result, in the entire glass substrate 30, properties of the neighboring thin film transistors 20 are different from each other, and a difference in display (for example, a difference in gradation or the like of a color) due to a difference in the properties does not appear in “a linear shape.” For this reason, display unevenness in the liquid crystal screen does not become “a stripe” and the display unevenness can be prevented from being emphasized.

In the third example, first, as exemplarily shown in FIG. 7, transmittances of the masks 150 included in the projection mask pattern 15 are set (adjusted) on the basis of properties of the microlenses 17. Specifically, transmittances of the projection mask patterns 15 are set (adjusted) on the basis of properties of the microlenses 17, which are previously ascertained. For example, when the energy density of the laser beams 14 passing through the one microlens 17 is high, transmittance of the projection mask pattern 15 disposed on the one microlens 17 is set to a low level. Meanwhile, when the energy density of the laser beams 14 passing through the other microlens 17 is low, transmittance of the projection mask pattern 15 disposed on the other microlens 17 is set to a high level.

After that, in the mask 150 to which transmittance is set on the basis of the properties of the microlenses 17, the transmittance of the mask 150 is further changed such that the transmittance is dispersed in the entire projection mask pattern 15 with reference to the set transmittance.

For example, the mask 150 to which transmittance is set to 90% further changes the transmittance of 90% at a proportion of a transmittance change assigned to the mask 150 to vary the transmittance on the entire projection mask pattern 15 on the basis of properties of the microlenses 17. For example, when a proportion of the transmittance change assigned to vary the transmittance on the entire projection mask pattern 15 is 95%, the mask 150 further changes a transmittance of 95% from 90%, resulting in a transmittance of 85.5%.

In this way, in the third example, the transmittance is changed to further vary the transmittance on the entire projection mask pattern 15 with reference to the transmittance set on the basis of the properties of the microlenses 17. As a result, the neighboring amorphous silicon thin films 21 can be irradiated with the laser beams 14 having different transmittances while reducing a difference in properties of the laser beams 14 due to properties of the plurality of microlenses 17 included in the microlens array 13.

As a result, since electron mobilities of the neighboring polysilicon thin films 22 can be differentiated from each other while reducing a difference in properties of the laser beams 14 occurred on the basis of the properties of the microlenses 17, in the entire glass substrate 30, properties of the neighboring thin film transistors 20 are different from each other, and a difference in display (for example, a difference in gradation or the like of a color) due to a difference in the properties does not appear in “a linear shape.” For this reason, display unevenness in the liquid crystal screen does not become “a stripe,” and the display unevenness can be prevented from being emphasized.

### Fourth Example

A fourth example is an example when laser annealing is performed using one projection lens 18 instead of the microlens array 13.

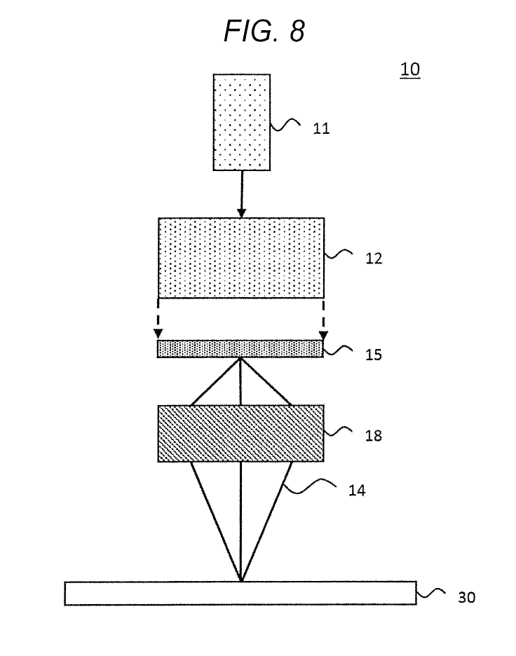

FIG. 8 is a view showing a configuration example of the laser irradiation apparatus 10 according to the fourth example. As shown in FIG. 8, the laser irradiation apparatus 10 according to the third example includes the laser source 11, the coupling optical system 12, the projection mask pattern 15 and the projection lens 18. Further, since the laser source 11 and the coupling optical system 12 have the same configurations as the laser source 11 and the coupling optical system 12 according to the first example shown in FIG. 1, detailed description will be omitted. In addition, since the projection mask pattern has the same configuration as the projection mask pattern according to the first example, detailed description will be omitted.

A laser beam passes through an opening (a transmissive region), not shown, of the projection mask pattern 15 exemplified in FIG. 6 and is radiated to a predetermined region of the amorphous silicon thin film 21 by the projection lens 18. As a result, a predetermined region of the amorphous silicon thin film 21 is instantly heated and melted, and a part of the amorphous silicon thin film 21 becomes the polysilicon thin film 22.

Even in the fourth example, the laser irradiation apparatus 10 radiates laser beams 14 at a predetermined period, the glass substrate 30 is moved while the laser beams 14 are not radiated, and the laser beams 14 are radiated to a place of the next amorphous silicon thin film 21. Even in the second example as shown in FIG. 3, the amorphous silicon thin films 21 are disposed on the glass substrate 30 at predetermined intervals “H” in a moving direction. Then, the laser irradiation apparatus 10 irradiates a portion of the amorphous silicon thin film 21 disposed on the glass substrate 30 with laser beams 14 at a predetermined period.

Here, when the projection lens 18 is used, the laser beams 14 are converted by a magnification of an optical system of the projection lens 18. That is, a pattern of the projection mask pattern 15 is converted by the magnification of the optical system of the projection lens 18, and a predetermined region on the glass substrate 30 is laser-annealed.

That is, a mask pattern of the projection mask pattern 15 is converted by the magnification of the optical system of the projection lens 18, and a predetermined region on the glass substrate 30 is laser-annealed. For example, when the magnification of the optical system of the projection lens 18 is about two times, the mask pattern of the projection mask pattern 15 becomes about ½ (0.5) times, and the predetermined region of the glass substrate 30 is laser-annealed. Further, the magnification of the optical system of the projection lens 18 is not limited to about two times and may be any magnification. In the mask pattern of the projection mask pattern 15, a predetermined region on the glass substrate 30 is laser-annealed according to the magnification of the optical system of the projection lens 18. For example, when the magnification of the optical system of the projection lens 18 is four times, the mask pattern of the projection mask pattern 15 becomes about ¼ (0.25) times, and a predetermined region on the glass substrate 30 is laser-annealed.

In addition, when the projection lens 18 forms an inverted image, a reduced image of the projection mask pattern 15 radiated to the glass substrate 30 is a pattern that is rotated about an optical axis of a lens of the projection lens 18 by 180 degrees. Meanwhile, when the projection lens 18 forms an erected image, a reduced image of the projection mask pattern 15 radiated to the glass substrate 30 is the projection mask pattern 15 as it is.

Further, in the single projection lens, for example, even when an irradiation light quantity or a magnification of a peripheral section is different from that of a central section due to an influence such as aberration or the like, uniform irradiation can be realized by changing transmittances of the masks 150 on the central section and the peripheral section of the projection mask pattern 15. For example, in the single irradiation lens, when an irradiation light quantity on the peripheral section is smaller than that of the central section, a transmittance of the mask 150 on the central section of the projection mask pattern 15 is increased, the transmittance of the mask 150 of the peripheral section is set to be lower than the transmittance of the central section, and thus, uniform irradiation can be realized on the entire projection mask pattern 15.

As described above, in the fourth example, even when laser annealing is performed using the one projection lens 18, the neighboring amorphous silicon thin films 21 can be irradiated with the laser beams 14 having different transmittances. As a result, in the entire glass substrate 30, properties of the neighboring thin film transistors 20 are different from each other, and a difference in display (for example, a difference in gradation or the like of a color) due to a difference in the properties does not appear in “a linear shape.” For this reason, display unevenness in the liquid crystal screen does not become “a stripe” and the display unevenness can be prevented from being emphasized.

Further, in the above-mentioned description, when “vertical,” “parallel,” “planar,” “perpendicular,” and the like, are disclosed, these disclosures are not strict meanings. That is, “vertical,” “parallel,” “planar” and “perpendicular” allow a tolerance or an error on design or manufacture, and mean “substantially vertical,” “substantially parallel,” “substantially planar” and “substantially perpendicular.” Further, the tolerance or error disclosed herein means a unit within a range that does not depart from a configuration, action and/or desired effect.

### Fifth Example

A fifth example is an example in which a resolving power of the microlens 17 having a relatively low resolving power is increased by applying a phase-shifting mask at a place corresponding to the microlens having a relatively low resolving power on the basis of resolving powers of the plurality of microlenses 17 included in the microlens array 13.

The plurality of microlenses 17 included in the microlens array 13 may have different resolving powers, which is one of the properties. That is, the microlens array 13 may include the microlens 17 having a relatively low resolving power. When the resolving power of the microlens 17 is low, light passing through the neighboring masks may not be correctly resolved and may not be annealed according to the pattern of the projection mask pattern 15. As a result, microcrystals may disturb the channel region of the thin film transistor 20 and adversely affect the display of the liquid crystal screen.

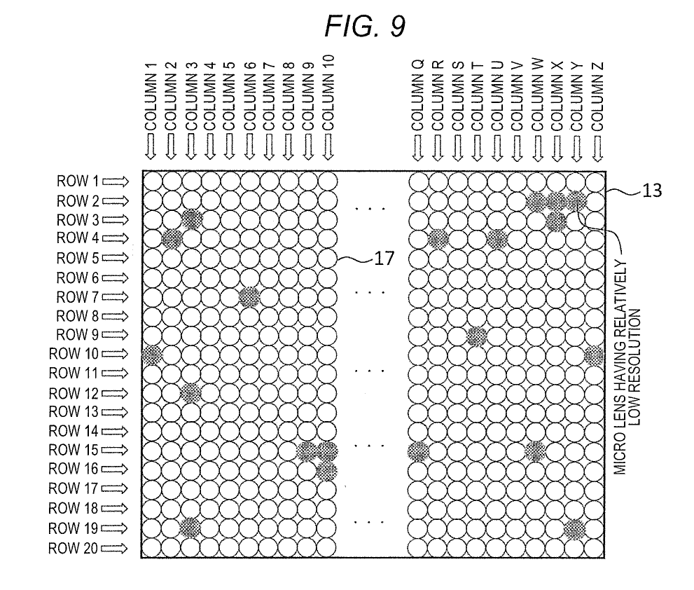

FIG. 9 is a view showing a configuration example of the microlenses 17 included in the microlens array 13. In the microlenses 17 shown in FIG. 9, for example, the microlenses 17 shown in gray have a resolving power that is relatively lower than that of the other microlenses 17 (the microlenses 17 shown in white). For this reason, when the laser irradiation apparatus 10 radiates laser beams 14 using the microlens array 13 exemplified in FIG. 9, it may be impossible to appropriately anneal the channel region of the thin film transistor 20 through the pattern of the projection mask pattern 15.

Meanwhile, to increase the resolving power of the microlens 17 having a relatively low resolving power, it is assumed to increase the resolving power of all of the microlenses 17 included in the microlens array 13. However, the resolving power of the other microlenses 17, i.e., the microlenses 17 having a relatively low resolving power is excessively increased, and a depth of focus (DOF) of the other microlenses 17 may be narrowed. As a result, a bad influence may be applied to a process of annealing of the channel region of the thin film transistor 20 using the microlens array 13. Accordingly, there is a limit to increasing the resolving power of all of the microlenses 17 included in the microlens array 13.

In the fifth example, in the plurality of microlenses 17 included in the microlens array 13, to increase the resolving power of the microlens 17 having a relatively low resolving power, the phase-shifting mask is used. Specifically, the phase-shifting mask is applied to the portion of the microlenses 17 having a relatively low resolving power, and a resolving power of the microlens 17 having a relatively low resolving power is increased. As a result, while a resolving power of the microlens 17 having a relatively low resolving power is increased, since the phase-shifting mask is not applied to the resolving power of the other microlenses 17, the resolving power of the other microlenses 17 is not increased excessively.

As a result, a difference in resolving powers of the plurality of microlenses 17 in the entire microlens array 13 can be reduced, annealing of the amorphous silicon of the thin film transistor 20 can be appropriately performed (i.e., annealing can be performed through a pattern of the masks), and application of a bad influence to the display of the liquid crystal screen can be suppressed.

Some of the plurality of microlenses 17 included in the microlens array 13 shown in FIG. 2 may have a resolving power that is lower than that of the other the microlenses 17 by, for example, 10%. Further, “10%” is merely exemplary, and the resolving powers of the plurality of microlens arrays 13 are different from each other within a range of 10% or more or 10% or less. A difference in resolving power of the microlenses 17 can be previously ascertained by, for example, irradiating the microlenses 17 with the laser beams 14 and measuring the resolving powers thereof.

In the fifth example, the phase-shifting mask is applied to the microlenses 17 having less than a predetermined resolving power on the basis of the resolving powers of the microlenses 17, which are previously ascertained.

The predetermined resolving power is, for example, a resolving power that is lower than an average value of the resolving powers of the plurality of microlenses 17 by 10% or more. Further, it is of course that 10% is merely exemplary and may be any value. In addition, the predetermined resolving power may be a resolving power (a fixed value) that is previously determined. The previously determined resolving power (fixed value) is a resolving power that can appropriately perform annealing of the amorphous silicon of the thin film transistor 20.

In addition, the microlens 17 to which the phase-shifting mask is applied may be determined on the basis of an incremental difference to the microlens 17 having the highest resolving power among the plurality of microlenses 17. That is, it is determined to apply the phase-shifting mask to the microlens 17 in which the highest resolving power and incremental difference of the microlens 17 are predetermined values or more.

Further, the microlens 17 to which the phase-shifting mask is applied may be determined in any way, and may be determined through any method as long as the microlens 17 that may not be appropriately annealed can be extracted while light passing through the neighboring masks is not resolved correctly.

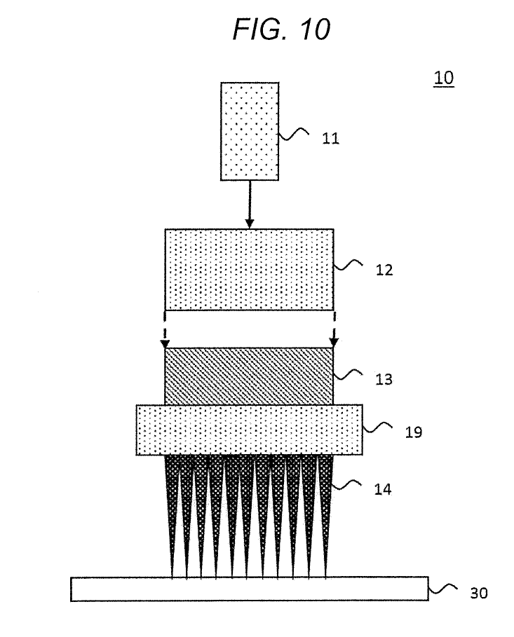

FIG. 10 is a view showing a configuration example of the laser irradiation apparatus 10 according to the fifth example. As shown in FIG. 10, the laser irradiation apparatus 10 according to the fifth example includes a phase-shifting mask 19 on the microlens array 13.

The phase-shifting mask (PSM) 19 is a mask that is able to control a phase or a transmittance of a laser beam 14, and can improve a resolution or a depth of focus of the microlens 17.

The phase-shifting mask 19 may be, for example, a halftone type phase-shifting mask, which is a mask capable of altering a phase of laser beam 14 passing through the microlens 17. In the halftone type phase-shifting mask, for example, when a translucent light shielding film (a phase shifter) is provided on the microlenses 17 and a propagation velocity of the laser beams 14 passing through the light shielding film is delayed, the phase of the laser beams 14 is altered to that extent. Then, when the laser beams 14 that pass through the translucent light shielding film to alter the phase and the laser beams 14 that do not pass through the translucent light shielding film not to alter the phase interfere with each other, a resolving power of the laser beams 14 can be improved.

Further, in the phase-shifting mask 19 according to the fifth example, like the projection mask pattern 15 of the above-mentioned example, a pattern for irradiating an amorphous silicon region of the thin film transistor 20 with laser beams 14 is provided on each of the microlenses 17 included in the microlens array 13. In addition, the phase-shifting mask 19 includes a configuration capable of improving a resolving power with respect to the microlens 17 having a low resolving power using, for example, a phase shifter.

In the laser irradiation apparatus 10 according to the fifth example, the phase-shifting mask 19 is applied to the microlens 17 having a relatively low resolving power, among the microlenses 17 included in the microlens array 13. Specifically, the phase-shifting mask 19 is applied to the microlens 17 having a relatively low resolving power (for example, the microlens 17 of a column 1 and a row 10, or a column 6 and a row 7) shown in FIG. 9. As a result, a resolving power of the microlens 17 having a relatively low resolving power can be improved, and the channel region of the thin film transistor 20 can be appropriately annealed through the pattern of the phase-shifting mask 19.

Meanwhile, the phase-shifting mask 19 is not applied to the other microlenses 17 (the microlenses 17 having resolving powers that are not relatively low). As a result, while the resolving power of the microlens 17 having the relatively low resolving power is improved, the resolving power of the other microlenses 17 remains as it is and the resolving power is not improved excessively. Accordingly, as a result, in the entire microlens array 13, a difference in resolving powers of the plurality of microlenses 17 can be reduced.

As described above, in the fifth example, a difference in resolving powers of the plurality of microlenses 17 in the entire microlens array 13 can be reduced, annealing of the amorphous silicon of the thin film transistor 20 can be appropriately performed (i.e., annealing can be performed through the pattern of the mask), and application of a bad influence to the display of the liquid crystal screen can be suppressed.

In addition, in the above-mentioned description, when there are descriptions such as “the same,” “equal,” “different,” and the like, in a dimension or a size on appearance, these descriptions are not strict meaning. That is, “the same,” “equal,” “different,” allow a tolerance or an error on design or manufacture, and mean “substantially the same,” “substantially equal,” and “substantially different.” Further, the tolerance or error disclosed herein means a unit within a range that does not depart from a configuration, action and/or desired effect.

While our apparatus and methods have been described based on the accompanying drawings and the above-mentioned examples, it should be noted that those skilled in the art can easily make various modifications and alterations based on this disclosure. Accordingly, these modifications and alterations are included within the scope of this disclosure. For example, functions included in each means, each step or the like, can be relocated not to be logically contradictory, and it is possible to combine a plurality of means, steps or the like, into one or divide them into several sets. In addition, configurations shown in the examples may be appropriately combined with each other.

1.-13. (canceled)

14. A laser irradiation apparatus comprising:
a light source configured to generate a laser beam;
a projection lens configured to irradiate a predetermined region of an amorphous silicon thin film deposited on each of a plurality of thin film transistors on a glass substrate with the laser beam; and
a projection mask pattern provided on the projection lens and comprising a plurality of masks for which transmittances that are proportions of the laser beams passing therethrough are set,
wherein the projection lens irradiates the plurality of thin film transistors on the glass substrate moving in a predetermined direction with the laser beam via the plurality of masks included in the projection mask pattern, and
each of the plurality of masks included in the projection mask pattern is set to any one of a plurality of transmittances.

15. The laser irradiation apparatus according to claim 14, wherein masks to which different transmittances are set are randomly disposed in the projection mask pattern.

16. The laser irradiation apparatus according to claim 14, wherein each of the plurality of masks included in the projection mask pattern is set to any one of the transmittances included in a predetermined range that is previously determined.

17. The laser irradiation apparatus according to claim 14, wherein the masks included in the projection mask pattern and neighboring in a column perpendicular to the predetermined direction have different transmittances.

18. The laser irradiation apparatus according to claim 14, wherein the plurality of masks included in the projection mask pattern have different transmittances.

19. The laser irradiation apparatus according to claim 14, wherein the projection lens is constituted of a plurality of microlenses included in a microlens array that are able to divide the laser beam, and
the plurality of masks included in the projection mask pattern correspond to the plurality of microlenses, respectively.

20. The laser irradiation apparatus according to claim 19, wherein transmittance of a mask corresponding to each of the microlenses in the projection mask pattern is set on the basis of the properties of the plurality of microlenses included in the microlens array.

21. The laser irradiation apparatus according to claim 19, wherein the projection mask pattern is a phase-shifting mask configured to increase a resolution of the microlens by altering a phase of a laser beam passing through the microlens, and
the phase-shifting mask alters a phase of a laser beam passing through a microlens determined on the basis of the resolution among the plurality of microlenses and increases resolution of the microlens.

22. The laser irradiation apparatus according to claim 19, wherein the phase-shifting mask alters a phase of the laser beam passing through the microlens having a relatively low resolution among the plurality of microlenses and increases the resolution of the microlens.

23. The laser irradiation apparatus according to claim 14, wherein the projection lens irradiates a predetermined region of an amorphous silicon thin film deposited between a source electrode and a drain electrode included in a thin film transistor with a laser beam and forms a polysilicon thin film.

24. A method of manufacturing a thin film transistor, comprising:
a first step of generating a laser beam;
a second step of irradiating a predetermined region of an amorphous silicon thin film deposited on a plurality of thin film transistors on a glass substrate with the laser beam using a projection lens on which a projection mask pattern including a plurality of masks, to which transmittances that are proportions of laser beams passing therethrough are set, is provided; and
a third step of moving the glass substrate in a predetermined direction whenever the laser beam is radiated,
wherein, in the second step, the laser beam is radiated via the projection mask pattern including the plurality of masks to which any one of the plurality of transmittances is set.

25. The method according to claim 24, wherein, in the second step, the laser beam is radiated via the projection mask pattern on which the masks, to which different transmittances are set, are randomly disposed.

26. The method according to claim 24, wherein, in the second step, the laser beam is radiated via the projection mask pattern including the mask to which any one of the transmittances included in a predetermined range that is previously determined is set.

27. The laser irradiation apparatus according to claim 15, wherein each of the plurality of masks included in the projection mask pattern is set to any one of the transmittances included in a predetermined range that is previously determined.

28. The laser irradiation apparatus according to claim 15, wherein the masks included in the projection mask pattern and neighboring in a column perpendicular to the predetermined direction have different transmittances.

29. The laser irradiation apparatus according to claim 16, wherein the masks included in the projection mask pattern and neighboring in a column perpendicular to the predetermined direction have different transmittances.

30. The laser irradiation apparatus according to claim 15, wherein the plurality of masks included in the projection mask pattern have different transmittances.

31. The laser irradiation apparatus according to claim 16, wherein the plurality of masks included in the projection mask pattern have different transmittances.

32. The laser irradiation apparatus according to claim 17, wherein the plurality of masks included in the projection mask pattern have different transmittances.

33. The laser irradiation apparatus according to claim 20, wherein the projection mask pattern is a phase-shifting mask configured to increase a resolution of the microlens by altering a phase of a laser beam passing through the microlens, and
the phase-shifting mask alters a phase of a laser beam passing through a microlens determined on the basis of the resolution among the plurality of microlenses and increases resolution of the microlens.
